(19) United States
(12) Patent Application Publication
(10) Pub. No.: US 2022/0373849 A1
(43) Pub. Date: Nov. 24, 2022

(54) TRANSPARENT THERMOELECTRIC SELFPOWERED GLAZING

(71) Applicant: SAGE ELECTROCHROMICS, INC., Faribault, MN (US)

(72) Inventors: Robert J. Anglemier, Waterville, MN (US); Cody VanDerVeen, Faribault, MN (US); Jean-Christophe Giron, Edina, MN (US)

(21) Appl. No.: 17/664,008

(22) Filed: May 18, 2022

Related U.S. Application Data
(60) Provisional application No. 63/189,936, filed on May 18, 2021.

(51) Int. Cl. G02F 1/1514; H01L 35/30; G02F 1/153; E06B 9/24; E06B 3/67; B32B 17/10

(52) U.S. Cl. CPC G02F 1/1514; H01L 35/30; G02F 1/1533; E06B 9/24; E06B 3/6722; B32B 17/10513; B32B 17/10036; B32B 17/10045; G02F 2203/01; E06B 2009/2464; B32B 2307/412; B32B 2307/202

(57) ABSTRACT

A glazing unit is disclosed. The glazing unit can include a first pane and an active device. The active device can be coupled to the first pane. The glazing unit can also include a thermoelectric film layer between the active device and the first pane. In one embodiment, the active device is an electrochromic device.

### CROSS-REFERENCE TO RELATED APPLICATION(S)

This application claims priority under 35 U.S.C. § 119(e) to U.S. Provisional Application No. 63/189,936, entitled “TRANSPARENT THERMOELECTRIC SELFPOWERED GLAZING,” by Robert J. ANGLEMIER et al., filed May 18, 2021, which is assigned to the current assignee hereof and incorporated herein by reference in its entirety.

### FIELD OF THE DISCLOSURE

The present disclosure is related to thermoelectric layers in electrochemical devices and the method of forming the same.

### BACKGROUND

An electrochemical device can include an electrochromic stack where transparent conductive layers are used to provide electrical connections for the operation of the stack. Electrochromic (EC) devices employ materials capable of reversibly altering their optical properties following electrochemical oxidation and reduction in response to an applied potential. The optical modulation is the result of the simultaneous insertion and extraction of electrons and charge compensating ions in the electrochemical material lattice.

As EC devices are incorporated into glazing units optical and energy related properties can vary. Insulated glazing units can include a double or triple pane series separated by spacers. Thermal energy can transfer across the gas cavity which ultimately affects the performance of the electrochromic device. Additionally, issues arise as the panes are hard wired into a building. Energy efficiency can be lost and power consumption can vary from pane to pane. Moreover, from a thermal standpoint, glazing whose transmission may be varied within at least part of the solar spectrum allows the solar heat influx into rooms that leads to excessive heating within a confined cavity, such as a room, building, airplane, or ship, etc.

As such, further improvements are sought in the context of electrochromic devices.

### BRIEF DESCRIPTION OF THE DRAWINGS

FIG. 1 is a schematic cross-section of a glazing unit with improved structure in accordance with an embodiment of the present disclosure.

FIG. 2 is a schematic cross-section of an electrochemical device in accordance with another embodiment of the present disclosure.

FIG. 3 illustrates a schematic view of a triple insulated glazing unit according to another embodiment of the current disclosure.

FIG. 4 illustrates a schematic view of a triple insulated glazing unit according to another embodiment of the current disclosure.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the invention.

### DETAILED DESCRIPTION

The following description in combination with the figures is provided to assist in understanding the teachings disclosed herein. The following discussion will focus on specific embodiments and embodiments of the teachings. This focus is provided to assist in describing the teachings and should not be interpreted as a limitation on the scope or applicability of the teachings.

As used herein, the terms “comprises,” “comprising,” “includes,” “including,” “has,” “having,” or any other variation thereof, are intended to cover a non-exclusive inclusion. For example, a process, method, article, or apparatus that comprises a list of features is not necessarily limited only to those features but may include other features not expressly listed or inherent to such process, method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Patterned features, which include bus bars, holes, holes, etc., can have a width, a depth or a thickness, and a length, wherein the length is greater than the width and the depth or thickness. As used in this specification, a diameter is a width for a circle, and a minor axis is a width for an ellipse.

The use of “a” or “an” is employed to describe elements and components described herein. This is done merely for convenience and to give a general sense of the scope of the invention. This description should be read to include one or at least one and the singular also includes the plural, or vice versa, unless it is clear that it is meant otherwise.

The use of the word “about,” “approximately,” or “substantially” is intended to mean that a value of a parameter is close to a stated value or position. However, minor differences may prevent the values or positions from being exactly as stated.

The solar heat gain coefficient (SHGC) of a glazing unit is either measured using the procedure described in the standard NFRC 201 or calculated using the process described in the standard NFRC 200 and in the EN410.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in textbooks and other sources within the glass, vapor deposition, and electrochromic arts.

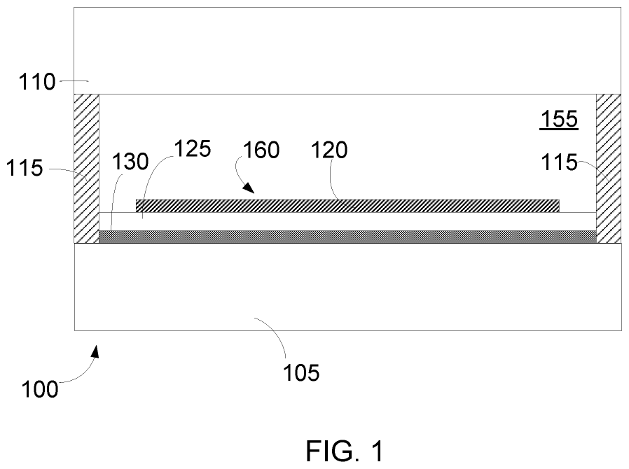

FIG. 1 is a schematic illustration of an insulated glazing unit 100 according to the embodiment of the current disclosure. Any of the electrochemical devices described herein can be processed as a part of an insulated glass unit 100. The insulated glass unit 100 can be incorporated into a window frame, a building, vehicle, room, airplane, ship, or other structure. The insulated glass unit 100 can include a first panel 105, an electrochemical device 120, a substrate 125, a second panel 110, a thermoelectric layer 130, and a spacer 115. In one embodiment, the first spacer 115 can be between the first panel 105 and second panel 110.

The first panel 105 can be a glass panel, a sapphire panel, an aluminum oxynitride panel, or a spinel panel. In another embodiment, the first panel can include a transparent polymer, such as a polyacrylic compound, a polyalkene, a polycarbonate, a polyester, a polyether, a polyethylene, a polyimide, a polysulfone, a polysulfide, a polyurethane, a polyvinylacetate, another suitable transparent polymer, or a co-polymer of the foregoing. The first panel 105 may or may not be flexible. In a particular embodiment, the first panel 105 can be float glass or a borosilicate glass and have a thickness in a range of 2 mm to 20 mm thick. The first panel 105 can be a heat-treated, heat-strengthened, or tempered panel. In one embodiment, the electrochemical device 120 can be coupled to first panel 105. In another embodiment, the electrochemical device 120 is on a substrate 125 and the substrate 125 is coupled to the first panel 105. In one embodiment, a thermoelectric film layer 130 may be disposed between the first panel 105 and the electrochemical device 120. In one embodiment, the thermoelectric film layer 130 may be disposed between the first panel 105 and the substrate 125 containing the electrochemical device 120. The electrochemical device 120 may be on a first side of the substrate 125 and the thermoelectric film layer 130 may be coupled to a second side of the substrate 125, where the first side is opposite and parallel to the second side.

The second panel 110 can be a glass panel, a sapphire panel, an aluminum oxynitride panel, or a spinel panel. In another embodiment, the second panel can include a transparent polymer, such as a polyacrylic compound, a polyalkene, a polycarbonate, a polyester, a polyether, a polyethylene, a polyimide, a polysulfone, a polysulfide, a polyurethane, a polyvinylacetate, another suitable transparent polymer, or a co-polymer of the foregoing. The second panel may or may not be flexible. In a particular embodiment, the second panel 110 can be float glass or a borosilicate glass and have a thickness in a range of 5 mm to 30 mm thick. The second panel 110 can be a heat-treated, heat-strengthened, or tempered panel. In one embodiment, the first spacer 115 can be between the first panel 105 and the second panel 110. In another embodiment, the first spacer 115 is between the substrate 125 and the second panel 110. In yet another embodiment, the first spacer 115 is between the electrochemical device 120 and the second panel 110.

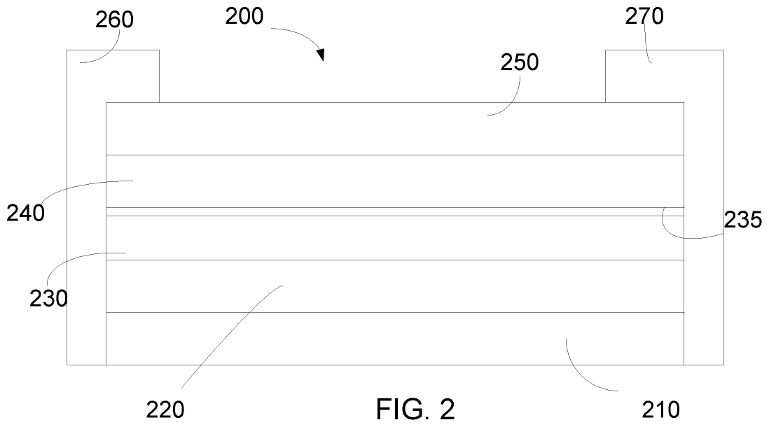

The electrochemical device 160 will be discussed in more detail below with respect to FIG. 2. The thermoelectric film layer 130 can be between the electrochemical device 160 and the first panel 105. In one embodiment, the thermoelectric film layer 130 can be transparent. In one embodiment, the thermoelectric film layer 130 can have a ZT value of between 1.4 and 2.4 at 450K. In one embodiment, the thermoelectric film layer 130 can include a material selected from the group consisting of bismuth telluride, alloys, bismuth selenide, thallium-doped lead telluride, alkali earth metals, polyethylene terephthalate, polycarbonate, poly (3,4-ethylenedioxythiophene):poly(styrene-sulfonate) (PEDOT:PSS), polyaniline, polypyrrole based polymers, and titanium disulfide. In one embodiment, the thermoelectric film layer has a thickness between 0.5 mm to 10 mm thick. Between the first pane 105 and the second pane 110 can be a cavity 155. Functionally, space 155 between the panes 105 and 110 can be insulating. As such, a temperature difference is created across the first pane 105 as heat travels from the exterior of the cavity 155 to within the cavity 155. As heat flows towards the cavity 155, the thermoelectric film layer can 130 take advantage of the heat flow to generate electricity for the electrochromic device and electrochromic control system. Additionally, the thermoelectric film layer 130 can help reduce the heat that would otherwise get trapped in cavity 155 by converting the heat into usable energy to power the electrochemical device. The thermoelectric film layer 130 can be coupled to a control panel (not shown) within the insulated glazing unit for the electrochromic device. As such, the embodiment of FIG. 1 advantageously allows an electrochemical device to be self-powered by taking advantage of the heat flow that otherwise could deteriorate the device. Additionally, since the thermal gradient across the insulated glazing unit can be high as temperatures differ from one side of the IGU to the opposite side of the IGU, the embodiment of FIG. 1 advantageously utilizes the heat to turn the potential energy into kinetic energy.

FIG. 2 illustrates a cross-section view of an active device 200 that can be a part of the glazing unit described above. In the embodiment of FIG. 2, the active device 200 is an electrochemical device 200. In one embodiment, the active device 200 can be a transparent/quasi transparent photovoltaic device, or more generally an energy harvesting device. In one embodiment, the active device 200 is an electrochemical device 200. In one embodiment, the electrochemical device 200 can be a variable transmission device. In one embodiment, the electrochemical device 200 can be an electrochromic device. In one embodiment, the active device 200 is a thin film battery. In another embodiment, the active device 200 is a solid state electrochromic. In yet another embodiment, the active device 200 is a liquid crystal device that might contain dichroic dyes. The active device can also be a thermochromic or photochromic device. In one embodiment, the active device can be a sound emitting and/or sound canceling device. However, it will be recognized that the present disclosure is similarly applicable to other types of scribed electroactive devices, electrochemical devices, as well as other electrochromic devices with different stacks or film structures (e.g., additional layers).

The electrochemical device 200 can include a substrate 210, a first transparent conductor layer 220, a cathodic electrochemical layer 230, an anodic electrochemical layer 240, and a second transparent conductor layer 250. In an embodiment, the substrate 210 can include a glass substrate, a sapphire substrate, an aluminum oxynitride substrate, or a spinel substrate. In another embodiment, the substrate 210 can include a transparent polymer, such as a polyacrylic compound, a polyalkene, a polycarbonate, a polyester, a polyether, a polyethylene, a polyimide, a polysulfone, a polysulfide, a polyurethane, a polyvinylacetate, another suitable transparent polymer, or a co-polymer of the foregoing. The substrate 210 may or may not be flexible. In a particular embodiment, the substrate 210 can be float glass or a borosilicate glass and have a thickness in a range of 0.5 mm to 12 mm thick. The substrate 210 may have a thickness no greater than 16 mm, such as 12 mm, no greater than 10 mm, no greater than 8 mm, no greater than 6 mm, no greater than 5 mm, no greater than 3 mm, no greater than 2 mm, no greater than 1.5 mm, no greater than 1 mm, or no greater than 0.01 mm. In another particular embodiment, the substrate 210 can include ultra-thin glass that is a mineral glass having a thickness in a range of 50 microns to 300 microns. In a particular embodiment, the substrate 210 may be used for many different electrochemical devices being formed and may be referred to as a motherboard.

Transparent conductive layers 220 and 250 can include a conductive metal oxide or a conductive polymer. Examples can include a tin oxide or a zinc oxide, either of which can be doped with a trivalent element, such as Al, Ga, In, or the like, a fluorinated tin oxide, or a sulfonated polymer, such as polyaniline, polypyrrole, poly(3,4-ethylenedioxythiophene), or the like. In another embodiment, the transparent conductive layers 220 and 250 can include gold, silver, copper, nickel, aluminum, or any combination thereof. The transparent conductive layers 220 and 250 can include indium oxide, indium tin oxide, doped indium oxide, tin oxide, doped tin oxide, zinc oxide, doped zinc oxide, ruthenium oxide, doped ruthenium oxide, and any combination thereof. The transparent conductive layers 220 and 250 can have the same or different compositions. The transparent conductive layers 220 and 250 can have a thickness between 10 nm and 600 nm. In one embodiment, the transparent conductive layers 220 and 250 can have a thickness between 200 nm and 500 nm. In one embodiment, the transparent conductive layers 220 and 250 can have a thickness between 320 nm and 460 nm. In one embodiment the first transparent conductive layer 220 can have a thickness between 10 nm and 600 nm. In one embodiment, the second transparent conductive layer 250 can have a thickness between 80 nm and 600 nm. The first transparent conductive layer 220 can be between the substrate 210 and the cathodic electrochemical layer 230. In one embodiment, the first transparent conductive layer 220 includes a P1 gap to prevent an electrical short of the electrochemical device 200. In one embodiment, the first transparent conductive layer 220 is electrically isolated from the second transparent conductive layer 250 through the P1 gap. In one embodiment, the second transparent conductive layer 250 of the device 200 can be a low-e layer.

The layers 230 and 240 can be electrode layers, wherein one of the layers may be a cathodic electrochemical layer, and the other of the layers may be an anodic electrochromic layer (also referred to as a counter electrode layer). In one embodiment, the cathodic electrochemical layer 230 is an electrochromic layer. The cathodic electrochemical layer 230 can include an inorganic metal oxide material, such as WO₃, V₂O₅, MoO₃, Nb₂O₅, TiO₂, CuO, Ni₂O₃, NiO, Ir₂O₃, Cr₂O₃, Co₂O₃, Mn₂O₃, mixed oxides (e.g., W—Mo oxide, W—V oxide), or any combination thereof and can have a thickness in a range of 40 nm to 600 nm. In one embodiment, the cathodic electrochemical layer 230 can have a thickness between 100 nm to 400 nm. In one embodiment, the cathodic electrochemical layer 230 can have a thickness between 350 nm to 390 nm. The cathodic electrochemical layer 230 can include lithium, aluminum, zirconium, phosphorus, nitrogen, fluorine, chlorine, bromine, iodine, astatine, boron; a borate with or without lithium; a tantalum oxide with or without lithium; a lanthanide-based material with or without lithium; another lithium-based ceramic material; or any combination thereof.

The anodic electrochromic layer 240 can include any of the materials listed with respect to the cathodic electrochromic layer 230 or Ta₂O₅, ZrO₂, HfO₂, Sb₂O₃, or any combination thereof, and may further include nickel oxide (NiO, Ni₂O₃, or combination of the two), and Li, Na, H, or another ion and have a thickness in a range of 40 nm to 500 nm. In one embodiment, the anodic electrochromic layer 240 can have a thickness between 150 nm to 300 nm. In one embodiment, the anodic electrochromic layer 240 can have a thickness between 250 nm to 290 nm. In some embodiments, lithium may be inserted into at least one of the first electrode 230 or second electrode 240.

In one embodiment, the device 200 may also include an ion conducting layer 235 between the cathodic electrochemical layer 230 and the anodic electrochemical layer 240. The ion conducting layer 235 may have a thickness between 1 nm and 20 nm. In one embodiment, the ion conducting layer 235 may have a thickness of no greater than 10 nm, such as no greater than 1 nm. The ion conducting layer 235 may contain material selected from the group consisting of lithium, sodium, oxidized lithium, Li₂WO₄, tungsten, nickel, lithium carbonate, lithium hydroxide, lithium peroxide, silicates, silicon oxides, tungsten oxides, tantalum oxides, niobium oxides, borates, aluminum oxides, lithium silicate, lithium aluminum silicate, lithium aluminum borate, lithium aluminum fluoride, lithium borate, lithium nitride, lithium zirconium silicate, lithium niobate, lithium borosilicate, lithium phosphosilicate, other lithium-based ceramic materials, lithium salts, and dopants including lithium, sodium, hydrogen, deuterium, potassium, calcium, barium, strontium, magnesium, and a combinations thereof. In one embodiment, ion conducting layer 235 can be oxidized.

In another embodiment, the device 200 may include a plurality of layers between the substrate 210 and the first transparent conductive layer 220. In one embodiment, an antireflection layer is between the substrate 210 and the first transparent conductive layer 220. The antireflection layer can include SiO₂, NbO₂, and can be a thickness between 20 nm to 100 nm. The device 200 may include at least two bus bars. In the embodiment of FIG. 2, two bus bars 260, 270 are shown. In one embodiment, the bus bar 260 can be electrically connected to the first transparent conductive layer 220 and the bus bar 270 can be electrically connected to the second transparent conductive layer 250. In another embodiment, bus bar 260 and bus bar 270 can be electrically connected to the first transparent conductive layer 220 with additional bus bars (not shown) being connected to the second transparent conductive layer 250.

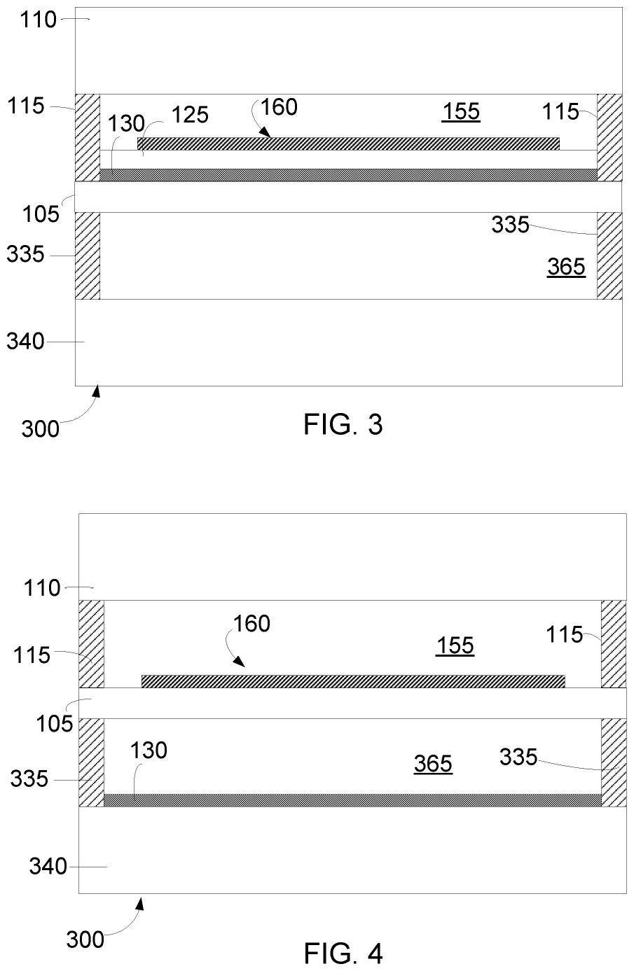

In another embodiment, the thermoelectric film layer can be utilized within a triple glazing unit, as show in FIG. 3. The triple glazing unit 300 can include additional layers and embodiments, such as seen in FIG. 3. FIG. 3 illustrates a schematic view of a triple insulated glazing unit 300 according to another embodiment of the current disclosure. The triple glazing unit 300 of FIG. 3 is substantially similar to the double glazing unit 100 of FIG. 1. In fact, the triple glazing unit 300 of FIG. 3 is a variant of the embodiment of FIG. 1, in which equivalent elements have been given identical reference numbers. As such, only additional features or differences from FIG. 1 are described below.

The triple glazing 300 can include a third pane 340, second spacer, 335, and a second cavity 365. As seen in FIG. 3, a thermoelectric film layer 370 can be between the electrochromic device 160 and a third pane 340. In one embodiment, the electrochemical device 160 and the thermoelectric film layer 130 are within a first cavity 155, as seen in FIG. 3. In another embodiment, the electrochemical device 160 can be within the first cavity 155 and the thermoelectric film layer 130 can be within a second cavity 365. In such an embodiment, the thermoelectric film layer 130 within the second cavity 365 can be coupled to the first pane 105. As such, the electrochromic device 160 can be couple to the pane 105 on a first side and the thermoelectric film layer 130 can be coupled to the pane 105 on a second side, where the first side and the second side are parallel and opposite. In another embodiment, the thermoelectric film layer 130 can be coupled to the third pane 340 and within the second cavity 365.

FIG. 4 illustrates a schematic view of a triple insulated glazing unit 400 according to another embodiment of the current disclosure. The triple glazing unit 400 of FIG. 4 is substantially similar to the triple glazing unit 300 of FIG. 3. In fact, the triple glazing unit 400 of FIG. 4 is a variant of the embodiment of FIG. 3, in which equivalent elements have been given identical reference numbers. As such, only additional features or differences from FIG. 4 are described below. As seen in FIG. 4, the internal or middle pane 105 can be a laminate. The electrochemical device 160 can be deposited directly on the pane 105 and the thermoelectric film layer 130 can be within a second cavity 365.

The embodiments described above and illustrated in the figures are not limited to rectangular shaped devices. Rather, the descriptions and figures are meant only to depict cross-sectional views of a device and are not meant to limit the shape of such a device in any manner. For example, the device may be formed in shapes other than rectangles (e.g., triangles, circles, arcuate structures, etc.). For further example, the device may be shaped three-dimensionally (e.g., convex, concave, etc.).

Many different aspects and embodiments are possible. Some of those aspects and embodiments are described below. After reading this specification, skilled artisans will appreciate that those aspects and embodiments are only illustrative and do not limit the scope of the present invention. Exemplary embodiments may be in accordance with any one or more of the ones as listed below.

Note that not all of the activities described above in the general description or the examples are required, that a portion of a specific activity may not be required, and that one or more further activities may be performed in addition to those described. Still further, the order in which activities are listed is not necessarily the order in which they are performed.

Certain features that are, for clarity, described herein in the context of separate embodiments, may also be provided in combination in a single embodiment. Conversely, various features that are, for brevity, described in the context of a single embodiment, may also be provided separately or in any subcombination. Further, reference to values stated in ranges includes each and every value within that range.

Embodiment 1. A glazing unit including: a first pane; an active device coupled to the first pane; and a thermoelectric film layer between the active device and the first pane.

Embodiment 2. A glazing unit including: a first pane; a second pane; an active device between the first pane and the second pane; and a thermoelectric film layer between the active device and the first pane.

Embodiment 3. A triple glazing unit including: a first pane; a second pane; a third pane between the first pane and the second pane; an active device between the first pane and the third pane; and a thermoelectric film layer between the active device and the second pane.

Embodiment 4. The glazing unit of embodiment 1 or embodiment 2 or the triple glazing unit of embodiment 3, where the thermoelectric film layer has a ZT value of between 1.4 and 2.4 at 450K.

Embodiment 5. The glazing unit of embodiment 1 or embodiment 2 or the triple glazing unit of embodiment 3, where the thermoelectric film includes a material selected from the group consisting of bismuth telluride, alloys, bismuth selenide, thallium-doped lead telluride, alkali earth metals, polyethylene terephthalate, polycarbonate, poly (3,4-ethylenedioxythiophene):poly(styrene-sulfonate) (PEDOT:PSS), polyaniline, polypyrrole based polymers, and titanium disulfide.

Embodiment 6. The glazing unit of embodiment 2, further including a first spacer between the first pane and the second pane, where the first pane, the first spacer, and the second pane form a first cavity.

Embodiment 7. The glazing unit of embodiment 1 or embodiment 2 or the triple glazing unit of embodiment 3, where the active device is an electrochromic device.

Embodiment 8. The glazing unit of embodiment 7, where the electrochromic device includes: a first transparent conductive layer; a second transparent conductive layer; a cathodic electrochemical layer between the first transparent conductive layer and the second transparent conductive layer; and an anodic electrochemical layer between the first transparent conductive layer and the second transparent conductive layer.

Embodiment 9. The glazing unit of embodiment 8, where the electrochromic device further includes a substrate, where the first transparent conductive layer is on the substrate.

Embodiment 10. The glazing unit of embodiment 9, where the substrate includes glass, sapphire, aluminum oxynitride, spinel, polyacrylic compound, polyalkene, polycarbonate, polyester, polyether, polyethylene, polyimide, polysulfone, polysulfide, polyurethane, polyvinylacetate, another suitable transparent polymer, co-polymer of the foregoing, float glass, borosilicate glass, or any combination thereof.

Embodiment 11. The glazing unit of embodiment 8, where the cathodic electrochemical layer includes WO₃, V₂O₅, MoO₃, Nb₂O₅, TiO₂, CuO, Ni₂O₃, NiO, Ir₂O₃, Cr₂O₃, Co₂O₃, Mn₂O₃, mixed oxides (e.g., W—Mo oxide, W—V oxide), lithium, aluminum, zirconium, phosphorus, nitrogen, fluorine, chlorine, bromine, iodine, astatine, boron, a borate with or without lithium, a tantalum oxide with or without lithium, a lanthanide-based material with or without lithium, another lithium-based ceramic material, or any combination thereof.

Embodiment 12. The glazing unit of embodiment 8, further including an ion-conducting layer between the cathodic electrochemical layer and the anodic electrochemical layer.

Embodiment 13. The glazing unit of embodiment 12, where the ion-conducting layer includes lithium, sodium, hydrogen, deuterium, potassium, calcium, barium, strontium, magnesium, oxidized lithium, Li₂WO₄, tungsten, nickel, lithium carbonate, lithium hydroxide, lithium peroxide, or an alkaline earth metal, transition metal, Zn, Ga, Ge, Al, Cd, In, Sn, Sb, Pb, Bi, B, Si, P, S, As, Se, Te, silicates, silicon oxides, tungsten oxides, tantalum oxides, niobium oxides, borates, aluminum oxides, lithium silicate, lithium aluminum silicate, lithium aluminum borate, lithium aluminum fluoride, lithium borate, lithium nitride, lithium zirconium silicate, lithium niobate, lithium borosilicate, lithium phosphosilicate, other lithium-based ceramic materials, lithium salts, and dopants including lithium, sodium, hydrogen, deuterium, potassium, calcium, barium, strontium, magnesium, or combinations thereof.

Embodiment 14. The glazing unit of embodiment 8, where the anodic electrochemical layer includes an inorganic metal oxide electrochemically active material, such as WO₃, V₂O₅, MoO₃, Nb₂O₅, TiO₂, CuO, Ir₂O₃, Cr₂O₃, Co₂O₃, Mn₂O₃, Ta₂O₅, ZrO₂, HfO₂, Sb₂O₃, a lanthanide-based material with or without lithium, another lithium-based ceramic material, a nickel oxide (NiO, Ni₂O₃, or combination of the two), and Li, nitrogen, Na, H, or another ion, any halogen, or any combination thereof.

Embodiment 15. The glazing unit of embodiment 8, where the first transparent conductive layer includes indium oxide, indium tin oxide, doped indium oxide, tin oxide, doped tin oxide, zinc oxide, doped zinc oxide, ruthenium oxide, doped ruthenium oxide, silver, gold, copper, aluminum, and any combination thereof.

Embodiment 16. The triple glazing unit of embodiment 3, where the thermoelectric film layer is coupled to the second pane.

Embodiment 17. The triple glazing unit of embodiment 3, where the thermoelectric film layer is coupled to the third pane.

Embodiment 18. The triple glazing unit of embodiment 3, where the active device and the thermoelectric film layer are within a first cavity, and where the first cavity is formed by the first spacer, the first pane, and the third pane.

Embodiment 19. The triple glazing unit of embodiment 3, where the active device is within a first cavity and the thermoelectric film layer is within a second cavity, where the first cavity is formed by the first spacer, the first pane, and the third pane, and where the second cavity is formed by the second spacer, the second pane, and the third pane.

Embodiment 20. The triple glazing unit of embodiment 3, where the active device is coupled to the third pane on a first side and the thermoelectric film layer is coupled to the third pane on a second side, and where the first side is opposite and parallel to the second side.

Embodiment 21. The glazing unit of embodiment 8, where the second transparent conductive layer includes indium oxide, indium tin oxide, doped indium oxide, tin oxide, doped tin oxide, zinc oxide, doped zinc oxide, ruthenium oxide, doped ruthenium oxide, and any combination thereof.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any subcombination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

What is claimed is:

1. A glazing unit comprising:
a first pane;
an active device coupled to the first pane; and
a thermoelectric film layer between the active device and the first pane.

2. The glazing unit of claim 1, wherein the thermoelectric film layer has a ZT value of between 1.4 and 2.4 at 450K.

3. The glazing unit of claim 1, wherein the thermoelectric film layer comprises a material selected from the group consisting of bismuth telluride, alloys, bismuth selenide, thallium-doped lead telluride, alkali earth metals, polyethylene terephthalate, polycarbonate, poly (3,4-ethylenedioxythiophene):poly(styrene-sulfonate) (PEDOT:PSS), polyaniline, polypyrrole based polymers, and titanium disulfide.

4. The glazing unit of claim 1, wherein the active device is an electrochromic device and wherein the electrochromic device comprises:
a first transparent conductive layer;
a second transparent conductive layer;
a cathodic electrochemical layer between the first transparent conductive layer and the second transparent conductive layer; and
an anodic electrochemical layer between the first transparent conductive layer and the second transparent conductive layer.

5. The glazing unit of claim 1, wherein the electrochromic device further comprises a substrate, wherein the first transparent conductive layer is on the substrate.

6. The glazing unit of claim 5, wherein the substrate comprises glass, sapphire, aluminum oxynitride, spinel, polyacrylic compound, polyalkene, polycarbonate, polyester, polyether, polyethylene, polyimide, polysulfone, polysulfide, polyurethane, polyvinylacetate, another suitable transparent polymer, co-polymer of the foregoing, float glass, borosilicate glass, or any combination thereof.

7. The glazing unit of claim 4, wherein the cathodic electrochemical layer comprises WO3, V2O5, MoO3, Nb2O5, TiO2, CuO, Ni2O3, NiO, Ir2O3, Cr2O3, Co2O3, Mn2O3, mixed oxides (e.g., W—Mo oxide, W—V oxide), lithium, aluminum, zirconium, phosphorus, nitrogen, fluorine, chlorine, bromine, iodine, astatine, boron, a borate with or without lithium, a tantalum oxide with or without lithium, a lanthanide-based material with or without lithium, another lithium-based ceramic material, or any combination thereof.

8. The glazing unit of claim 4, further comprising an ion-conducting layer between the cathodic electrochemical layer and the anodic electrochemical layer.

9. The glazing unit of claim 8, wherein the ion-conducting layer comprises lithium, sodium, hydrogen, deuterium, potassium, calcium, barium, strontium, magnesium, oxidized lithium, Li2WO4, tungsten, nickel, lithium carbonate, lithium hydroxide, lithium peroxide, or an alkaline earth metal, transition metal, Zn, Ga, Ge, Al, Cd, In, Sn, Sb, Pb, Bi, B, Si, P, S, As, Se, Te, silicates, silicon oxides, tungsten oxides, tantalum oxides, niobium oxides, borates, aluminum oxides, lithium silicate, lithium aluminum silicate, lithium aluminum borate, lithium aluminum fluoride, lithium borate, lithium nitride, lithium zirconium silicate, lithium niobate, lithium borosilicate, lithium phosphosilicate, other lithium-based ceramic materials, lithium salts, and dopants including lithium, sodium, hydrogen, deuterium, potassium, calcium, barium, strontium, magnesium, or combinations thereof.

10. The glazing unit of claim 4, wherein the anodic electrochemical layer comprises an inorganic metal oxide electrochemically active material, such as WO3, V2O5, MoO3, Nb2O5, TiO2, CuO, Ir2O3, Cr2O3, Co2O3, Mn2O3, Ta2O5, ZrO2, HfO2, Sb2O3, a lanthanide-based material with or without lithium, another lithium-based ceramic material, a nickel oxide (NiO, Ni2O3, or combination of the two), and Li, nitrogen, Na, H, or another ion, any halogen, or any combination thereof.

11. The glazing unit of claim 4, wherein the first transparent conductive layer comprises indium oxide, indium tin oxide, doped indium oxide, tin oxide, doped tin oxide, zinc oxide, doped zinc oxide, ruthenium oxide, doped ruthenium oxide, silver, gold, copper, aluminum, and any combination thereof.

12. The glazing unit of claim 4, wherein the second transparent conductive layer comprises indium oxide, indium tin oxide, doped indium oxide, tin oxide, doped tin oxide, zinc oxide, doped zinc oxide, ruthenium oxide, doped ruthenium oxide, and any combination thereof.

13. A glazing unit comprising:
a first pane;
a second pane;
an active device between the first pane and the second pane; and
a thermoelectric film layer between the active device and the first pane.

14. The glazing unit of claim 13, further comprising a first spacer between the first pane and the second pane, wherein the first pane, the first spacer, and the second pane form a first cavity.

15. A triple glazing unit comprising:
a first pane;
a second pane;
a third pane between the first pane and the second pane;
an active device between the first pane and the third pane; and
a thermoelectric film layer between the active device and the second pane.

16. The triple glazing unit of claim 15, wherein the thermoelectric film layer is coupled to the second pane.

17. The triple glazing unit of claim 15, wherein the thermoelectric film layer is coupled to the third pane.

18. The triple glazing unit of claim 15, wherein the active device and the thermoelectric film layer are within a first cavity, and wherein the first cavity is formed by the first spacer, the first pane, and the third pane.

19. The triple glazing unit of claim 15, wherein the active device is within a first cavity and the thermoelectric film layer is within a second cavity, wherein the first cavity is formed by the first spacer, the first pane, and the third pane, and wherein the second cavity is formed by the second spacer, the second pane, and the third pane.

20. The triple glazing unit of claim 15, wherein the active device is coupled to the third pane on a first side and the thermoelectric film layer is coupled to the third pane on a second side, and wherein the first side is opposite and parallel to the second side.
